(19) United States
(12) Patent Application Publication
(10) Pub. No.: US 2019/0069669 A1
(43) Pub. Date: Mar. 7, 2019

(54) Elliptically Rotating Cable Organizing Device

(71) Applicants: David R. Hall, Provo, UT (US); William H. Reynolds, Orem, UT (US); Christopher Reynolds, Orem, UT (US)

(72) Inventors: David R. Hall, Provo, UT (US); William H. Reynolds, Orem, UT (US); Christopher Reynolds, Orem, UT (US)

(21) Appl. No.: 15/694,053

(22) Filed: Sep. 1, 2017

(51) Int. Cl. A47B 21/06; A47B 21/02; F16L 3/26; H05K 7/18; H05K 7/20

(52) U.S. Cl. CPC A47B 21/06; A47B 21/02; F16L 3/26; H05K 7/18; A47B 2200/008; A47B 2021/066; A47B 2200/0054; A47B 2200/0057; A47B 2200/0058; H05K 7/20136

(57) ABSTRACT

A cable organizing device is disclosed. A tray, mountable adjacent an underside of a working surface, comprises opposed side walls and a distal back wall joined by a tray floor, the tray floor comprising a U-shaped trough along a proximal side forming a front side wall of the tray. The distal back wall comprises notches along its upper edge opposite the floor. A distal portion of the side walls comprises mounting tabs comprising an eccentric hinge point around which the tray rotates elliptically, rotating the back wall of the tray away from the underside of the working surface. As the tray is rotated away from the underside of the working surface an opening is formed above the back wall to allow electrical cable components to pass the notches into the tray and loose cable components in the tray slide into the U-shaped trough.

### FIELD OF THE INVENTION

This invention relates generally to cable management.

### BACKGROUND

Organization of cables at desks, tables, workbenches, and shelves is a general problem wherever a plurality of cables is required. Organization of these cables is accomplished in various ways, but one of the most successful is to use trays. However, most cable trays are insufficient for easy, day to day use. Cable trays that are easy to use and keep organized for day to day use are needed.

U.S. Pat. No. 5,934,201, to Diffrient, teaches a table with a wire manager. The folding table has two C-leg assemblies and a wire tray either in the legs or behind the legs and under the back edge of the tabletop. The present disclosure differs from this prior art disclosure in that the wire tray extends along the length of the tabletop, not just between the legs, uses an access door rather than having the entire wire tray open, has a piano hinge for the access door, and other differences apparent to those of normal skill in the art. This prior art disclosure is pertinent and may benefit from the devices disclosed herein and is hereby incorporated by reference in its entirety for all that it teaches.

U.S. Pat. No. 5,640,912, to Diffrient teaches a foldable table with a detachable wire management tray. The foldable table has a wire management tray that is removable for convenience when the table is folded. The present disclosure differs from this disclosure at least in that the wire tray is removable, the wire tray attaches by hooks on pins, the wire tray does not span the entire distance between table legs, the wire tray is not hinged, and other differences apparent to those of normal skill in the art. This disclosure is pertinent and may benefit from the devices disclosed herein and is hereby incorporated by reference in its entirety for all that it teaches.

U.S. Pat. No. 6,003,447, to Cox, et al., teaches a folding table with a removable wire gallery. The wire gallery, or wireway, is removably attached to the leg braces. The present disclosure differs from this disclosure in that the wireway is not directly below the tabletop and requires an additional cover, the wireway is removable, the wireway is not hinged (the hinge referenced as attached to the wireway is for attaching a screen), and other differences apparent to those of normal skill in the art. This disclosure is pertinent and may benefit from the devices disclosed herein and is hereby incorporated by reference in its entirety for all that it teaches.

U.S. Pat. No. 6,609,465, to Kolavo, teaches a multiple purpose table for use with tower-style desktop computers. The present disclosure differs from this disclosure in that the cable tray disclosed consists of a trough attached to a vertical panel, with no cover or hinges. This disclosure is pertinent and may benefit from the devices disclosed herein and is hereby incorporated by reference in its entirety for all that it teaches.

U.S. Pat. No. 5,769,514, to Brown, et al., teaches a ready to use foldable computer desk. A cable tray is used for power and other computer cables. The present disclosure differs from this disclosure in that the cable trays are not hinged and do not extend from table leg to table leg. This disclosure is pertinent and may benefit from the devices disclosed herein and is hereby incorporated by reference in its entirety for all that it teaches.

### SUMMARY

A cable organizing device is disclosed. A tray, mountable adjacent an underside of a working surface, comprises opposed side walls and a distal back wall joined by a tray floor, the tray floor comprising a U-shaped trough along a proximal side forming a front side wall of the tray. The distal back wall comprises notches along its upper edge opposite the floor. A distal portion of the side walls comprises mounting tabs comprising an eccentric hinge point around which the tray rotates elliptically, rotating the back wall of the tray away from the underside of the working surface. As the tray is rotated away from the underside of the working surface an opening is formed above the back wall to allow electrical cable components to pass the notches into the tray and loose cable components in the tray slide into the U-shaped trough.

The working surface may comprise a desktop, a tabletop, a seat of a chair, a workbench, or a shelf. The desktop may be mounted on two parallel crossbeams which are mounted on two legs. The tray may be mounted between the two parallel crossbeams. The tray may be shaped to match an underside profile of the working surface when the tray is closed. The desktop may be further mounted on a perpendicular crossbeam, the U-shaped trough aligning with a bottom portion of the perpendicular crossbeam. A distal wall of the perpendicular crossbeam may be proximate to an interior of the cable tray, the distal wall comprising one or more holes through which cables are passed. The two legs may comprise motors which automatically raise and lower the desk, and the cables for the motors pass through the cable tray via the perpendicular crossbeam. The tray may be prevented from opening when the desk is lowered.

The U-shaped trough may comprise an attachment apparatus that holds the tray closed by attaching to the underside of the working surface. The latching apparatus may comprise a hook, a latch, a hasp, a slide bolt, a magnet, pins, or combinations thereof. The latching apparatus may further comprise a lock.

The cable organizing device in a fully-open position may be substantially perpendicular to the cable organizing device in a fully-closed position. The rotation of the hinge points may be hindered such that the tray rotates opens slowly.

A fan may be provided mounted through at least one sidewall to cool electrical components stored in the tray.

The tray floor may comprise hook and loop, double-sided detachable tape, Pedalboard® tape, or combinations thereof, to which electrical components are removably attached.

One or more motors may rotate the tray around the hinge points.

One or more electrical sockets may be mounted to the distal back wall. A power cable for the one or more electrical cables may pass through a gap in a lower portion of the distal back wall.

### BRIEF DESCRIPTION OF THE DRAWINGS

In order that the advantages of the invention will be readily understood, a more particular description of the invention briefly described above will be rendered by reference to specific embodiments illustrated in the appended drawings. Understanding that these drawings depict only typical embodiments of the invention and are not therefore to be considered limiting of its scope, the invention will be described and explained with additional specificity and detail through use of the accompanying drawings, in which:

FIG. 1A shows an isometric view of a cable organizing device from a proximal, side view.

FIG. 1B shows an isometric view of the cable organizing device of FIG. 1A from a proximal, top view.

FIG. 1C shows an isometric view of the cable organizing device of FIG. 1A from a distal view.

FIG. 2A shows an isometric front, right view of an extended version of a desk frame with the cable organizing device of FIG. 1A in a closed position.

FIG. 2B shows a front view of the extended version of the desk frame of FIG. 2A, with the cable organizing device in the closed position.

FIG. 2C shows an isometric front, right view of a lowered version of the desk frame of FIG. 2B, with the cable organizing device in a partially open position.

FIG. 2D shows a front view of the lowered version of the desk frame of FIG. 2A, with the cable organizing device in the partially open position.

FIG. 2E shows a front, isometric close-up view of the right side of the desk frame of FIG. 2A, with the cable organizing device in the closed position.

FIG. 2F shows a back, isometric close-up view of the right side of the desk frame of FIG. 2A, with the cable organizing device in the closed position.

FIG. 2G shows an isometric side view of the right side of the desk frame of FIG. 2A, with the cable organizing device in the closed position and the desktop represented.

FIG. 2H shows a side view of the right side of the desk frame of FIG. 2A, with the cable organizing device in the closed position and the desktop represented.

FIG. 2I shows an isometric side view of the right side of the desk frame of FIG. 2A, with the cable organizing device in the closed position, the desktop represented, and mounting plates removed.

FIG. 2J shows an isometric side view of the right side of the desk frame of FIG. 2A, with the cable organizing device in the open position, the desktop represented, and mounting plates removed.

### DETAILED DESCRIPTION

It will be readily understood that the components of the present invention, as generally described and illustrated in the Figures herein, could be arranged and designed in a wide variety of different configurations. Thus, the following more detailed description of the embodiments of the invention, as represented in the Figures, is not intended to limit the scope of the invention, as claimed, but is merely representative of certain examples of presently contemplated embodiments in accordance with the invention.

The term “cable organizing device,” when used herein, also refers to trays, cable trays, wire trays, wireways, wire runs, cable runs, wire galleries, cable managers, wall trays, Panduit®, cable protectors, wiring ducts, snake races, snake trays, wire races, wire baskets, ladder trays, ventilated trays, raceways, runways, cable trunks, cable chains, cable ducts, or other cable and wire management systems.

The term “desk,” when used herein, also refers to tables, work benches, or other horizontal surfaces.

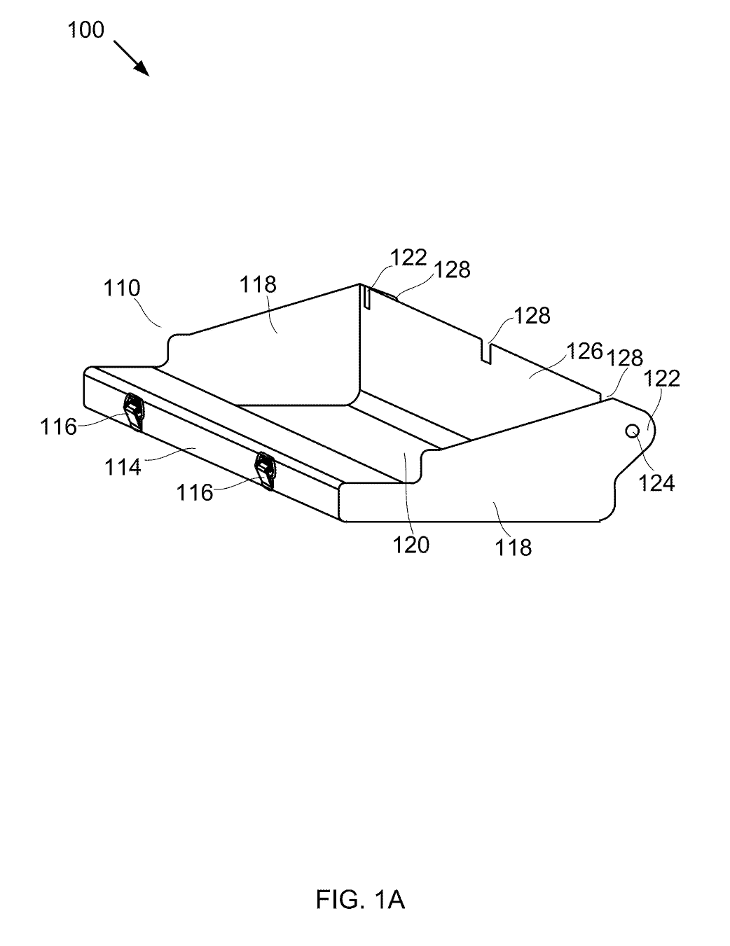

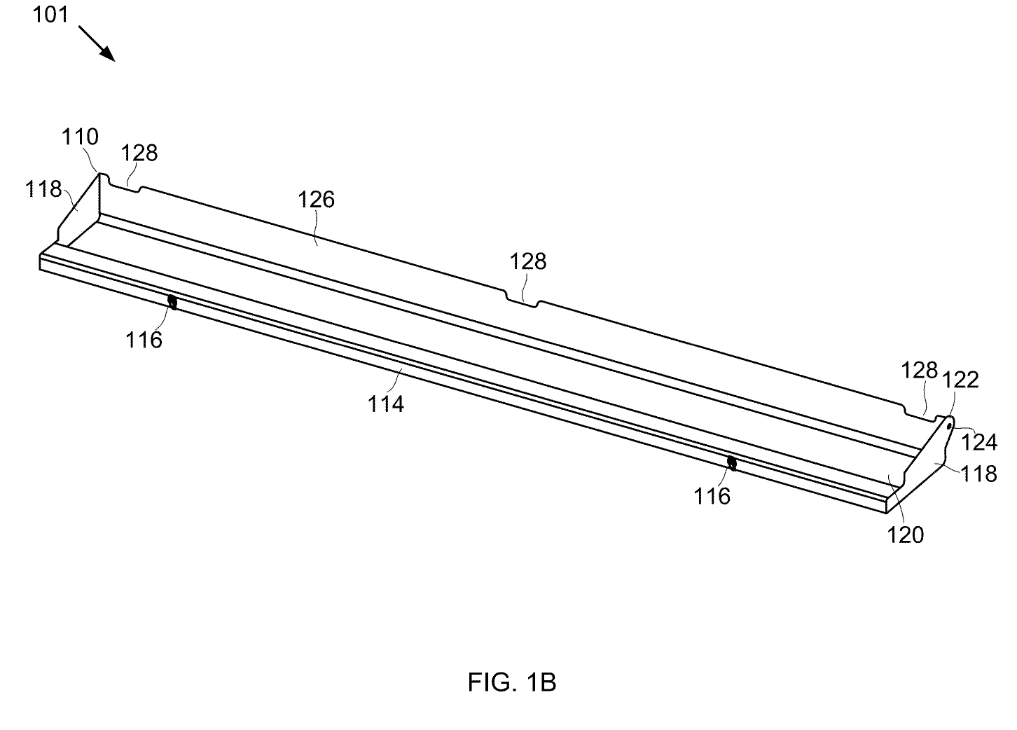

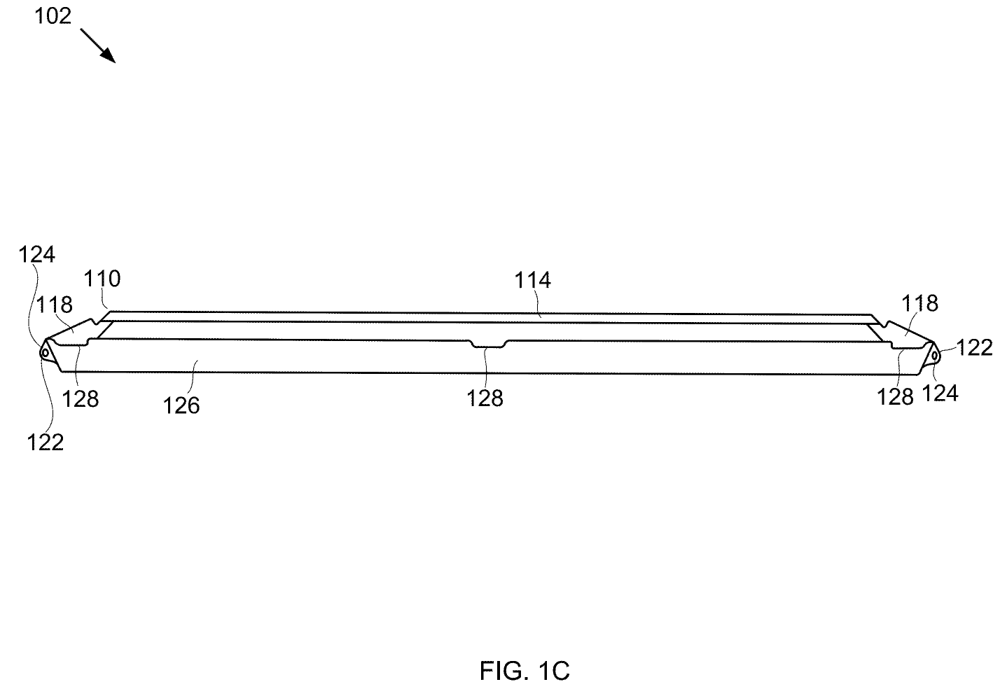

Referring to FIG. 1A, an isometric view of a cable organizing device from a proximal, side view is shown at 100, as per one embodiment of the present invention.

Referring to FIG. 1B, an isometric view of the cable organizing device of FIG. 1A is shown from a proximal, top view at 101.

Referring to FIG. 1C, an isometric view of a cable organizing device of FIG. 1A is shown from a distal view at 102.

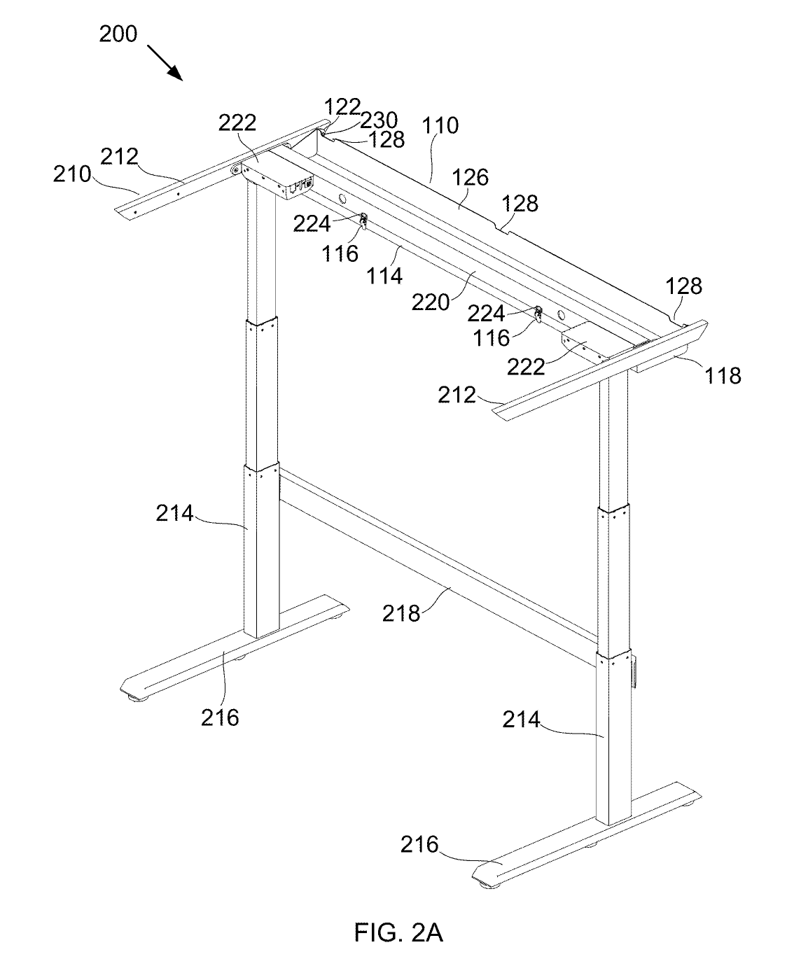

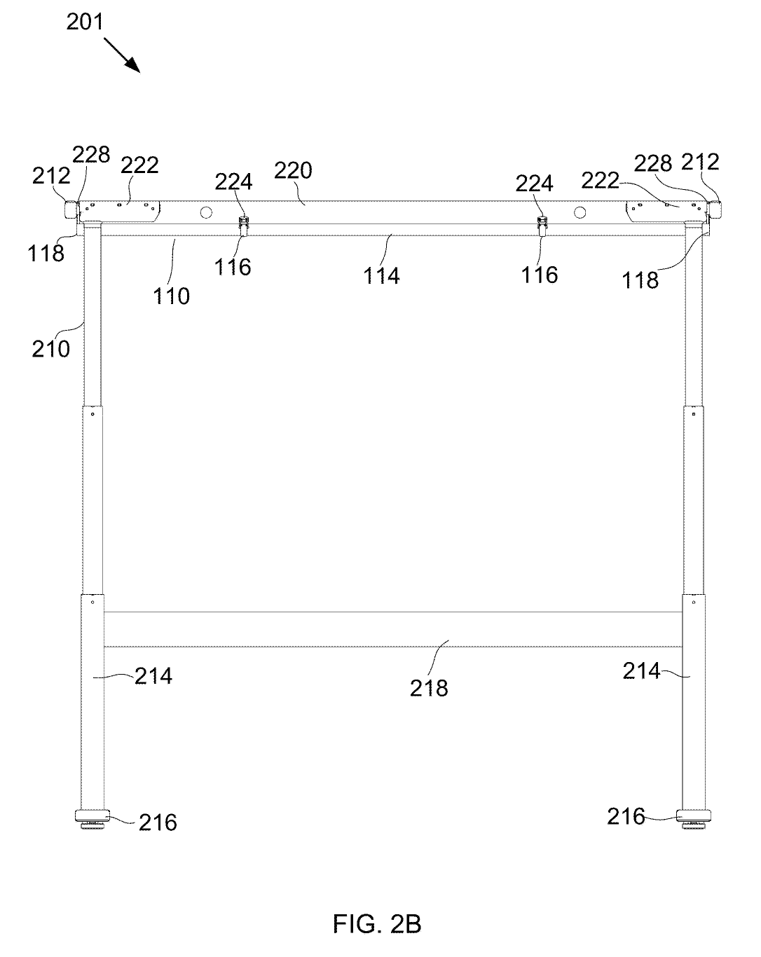

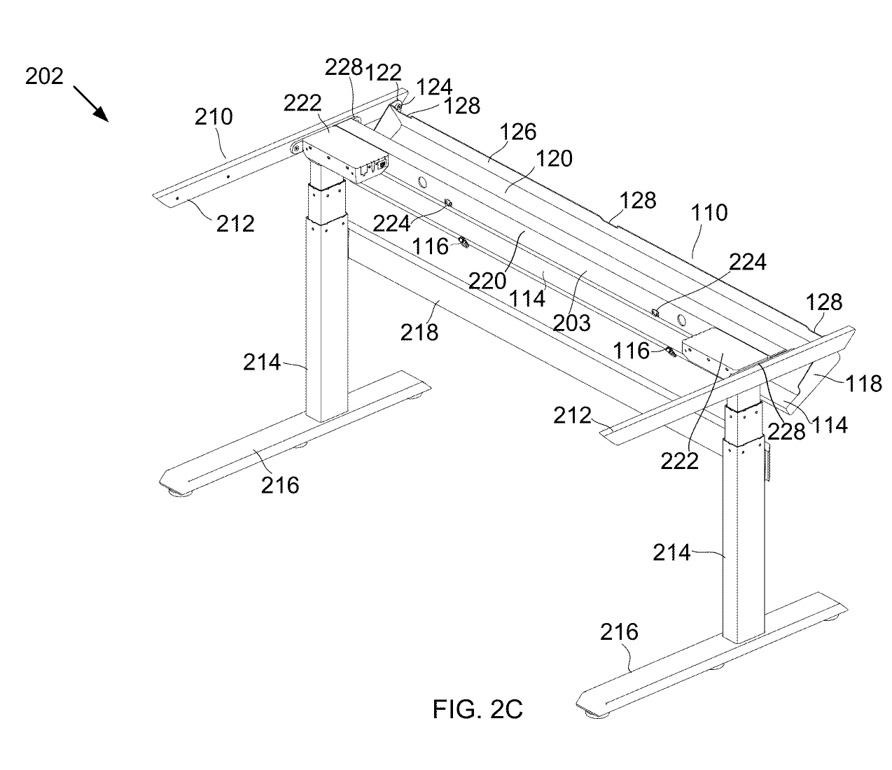

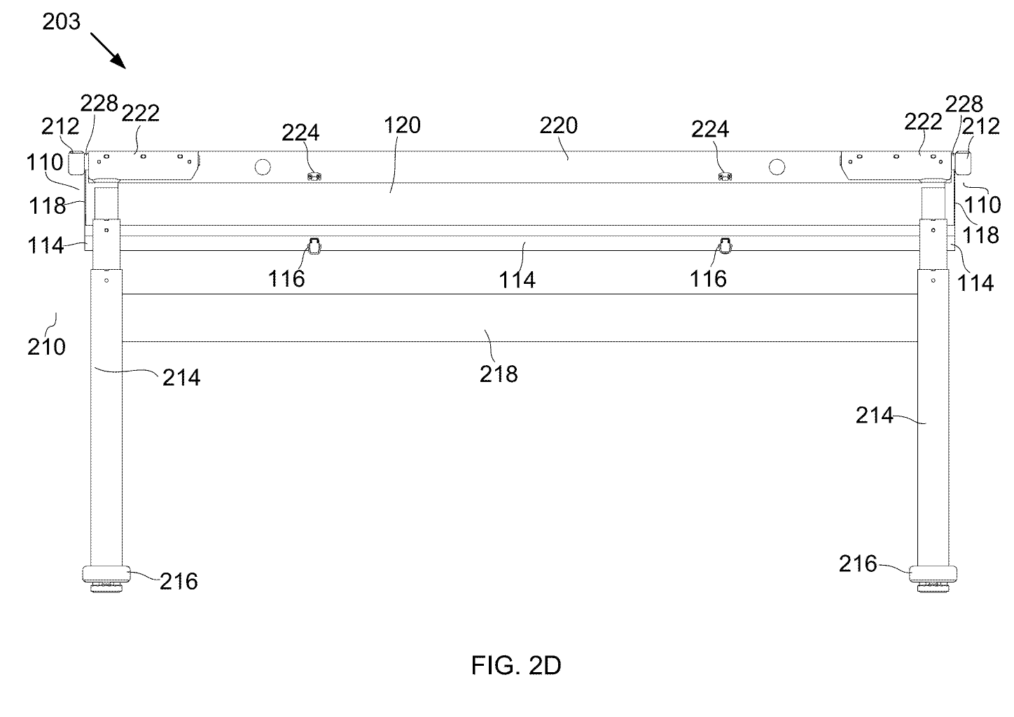

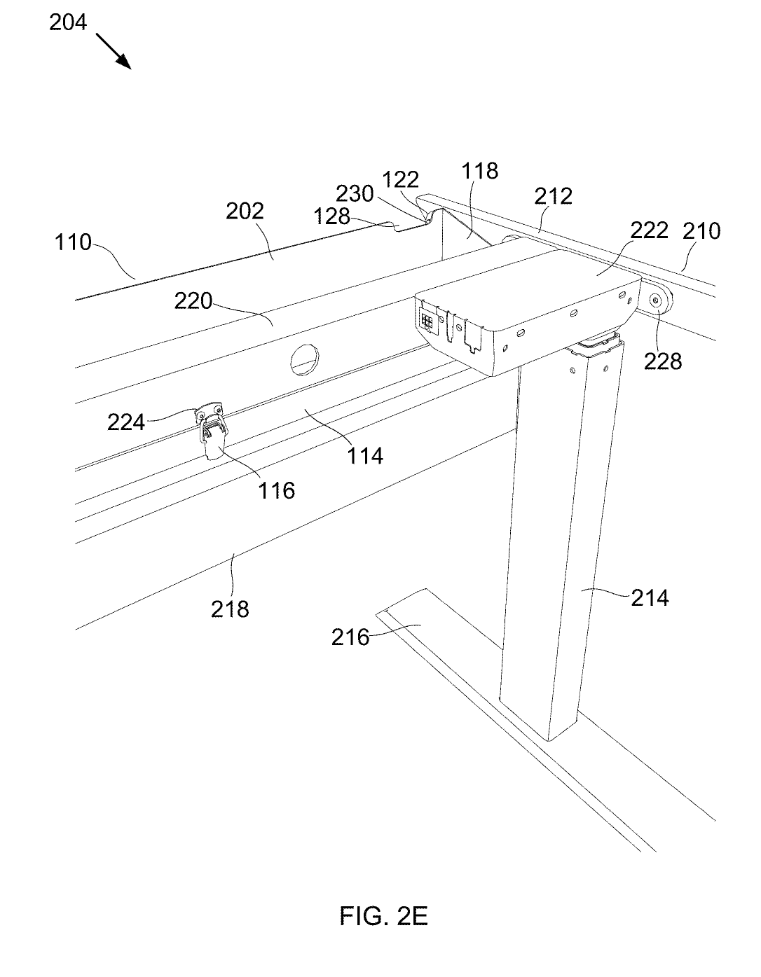

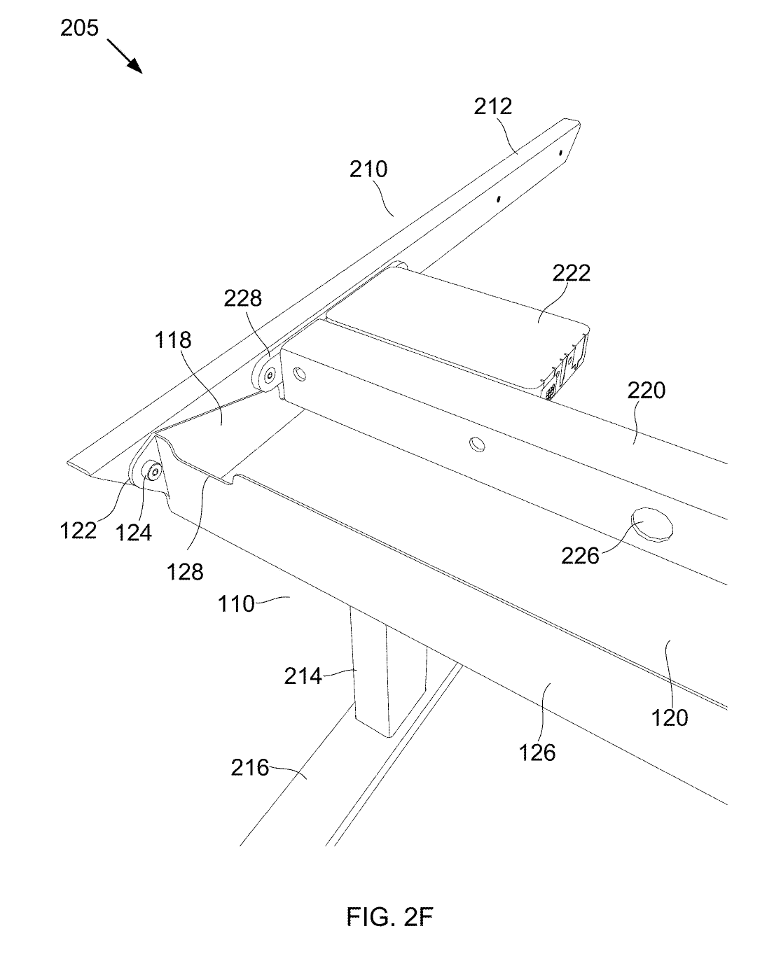

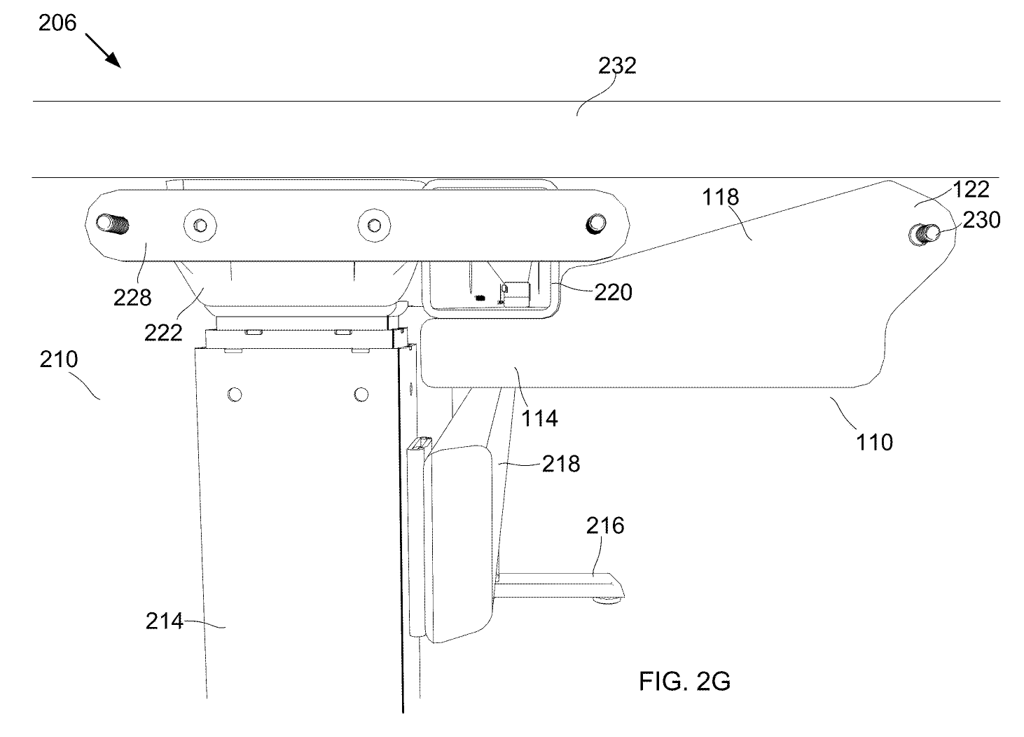

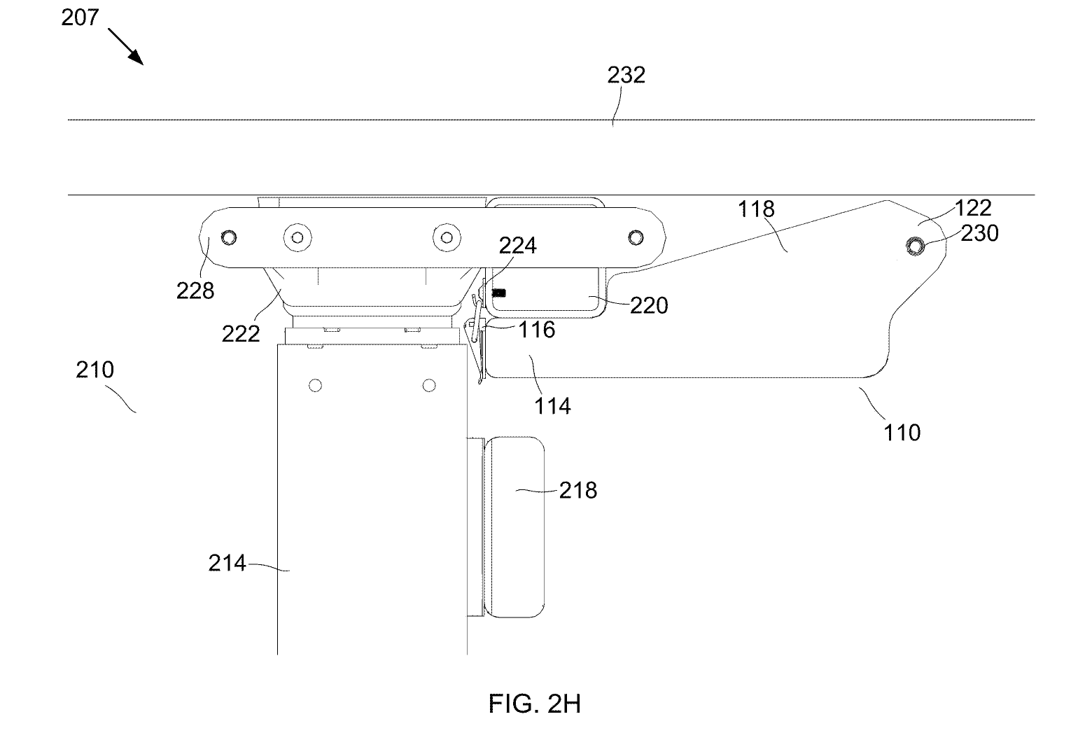

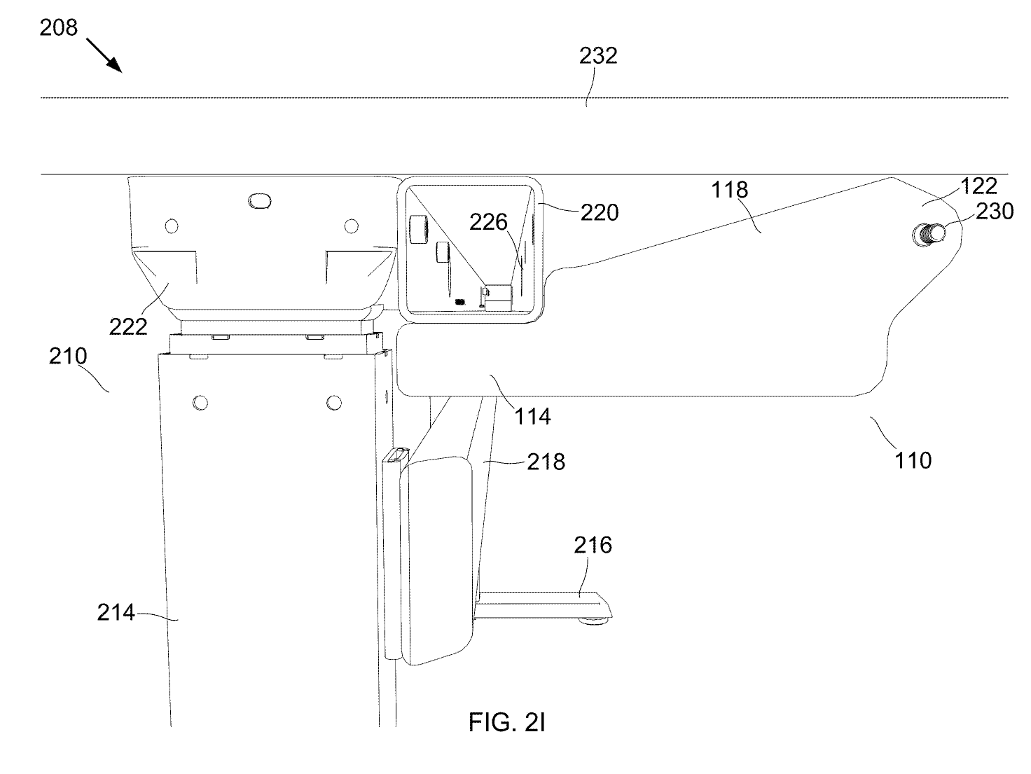

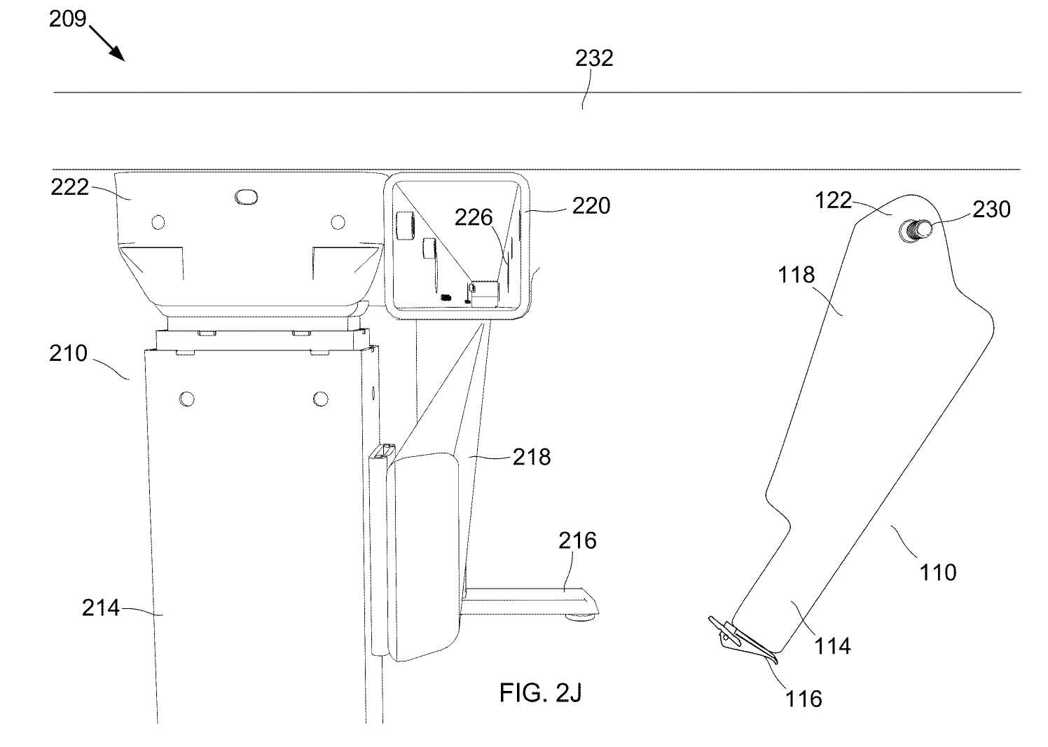

Tray 110, mountable adjacent an underside of a working surface (see FIG. 2), comprises opposed side walls 118, distal back wall 126 joined by tray floor 120, tray floor 120 comprising U-shaped trough 114 along a proximal side forming a front side wall of the tray. Distal back wall 126 comprises notches 128 along its upper edge opposite floor 120. A distal portion of side walls 118 comprises mounting tabs 122 comprising eccentric hinge points 124 around which tray 110 rotates elliptically, rotating back wall 126 of tray 110 away from the underside of the working surface. As tray 110 is rotated away from the underside of the working surface an opening is formed above back wall 126 to allow electrical cable components to pass through notches 128 into tray 110 and loose cable components in tray 110 slide into trough 114. Latches 116 are mounted on trough 114, latches 116 used to close tray 110 against the working surface.

Referring to FIG. 2A, an isometric front, right view of an extended version of a desk frame with the cable organizing device of FIG. 1A in a closed position is shown at 200, as per one embodiment of the present invention. Desk frame 210 is shown without a desktop for clarity of view, except in FIGS. 2G-J, where it is shown as desktop 232. The desktop is the working surface. Tray 110 is mounted between parallel crossbeams 212 through hinge point 124 by bolt 230. Parallel crossbeams 212 are mounted on legs 214, which are mounted on leg supports 216. Perpendicular crossbeams 218 and 220 provide support between legs 214 and between parallel crossbeams 212. Desktop 232 mounts on parallel crossbeams 212. Motors 222 are mounted through mounting plates 228 to parallel crossbeams 212. Motors 222 cause legs 214 to extend or retract telescopically. Holes 226 in perpendicular beam 220 allow cables from motors 222 to pass into cable tray 110. Latches 116 of tray 110 latch to hooks 224 to hold tray 110 in a closed position (FIGS. 2A-B, E-I). Unlatching latches 116 allows tray 110 to swing around hinge point 124/bolt 230 to an open position (FIGS. 2C-D, J). The rotation opens a gap between desktop 232 and the top of back wall 126 that allows electrical cable components to pass notches 128 into tray 110 and loose cable components in tray 110 slide into trough 114.

Referring to FIG. 2B, a front view of the extended version of the desk frame of FIG. 2A, with the cable organizing device in the closed position, is shown at 201.

Referring to FIG. 2C, an isometric front, right view of a lowered version of the desk frame of FIG. 2B, with the cable organizing device in a partially open position, is shown at 202.

Referring to FIG. 2D, a front view of the lowered version of the desk frame of FIG. 2A, with the cable organizing device in the partially open position, is shown at 203.

Referring to FIG. 2E, a front, isometric close-up view of the right side of the desk frame of FIG. 2A, with the cable organizing device in the closed position, is shown at 204.

Referring to FIG. 2F, a back, isometric close-up view of the right side of the desk frame of FIG. 2A, with the cable organizing device in the closed position, is shown at 205.

Referring to FIG. 2G, an isometric side view of the right side of the desk frame of FIG. 2A, with the cable organizing device in the closed position and the desktop represented, is shown at 206.

Referring to FIG. 2H, a side view of the right side of the desk frame of FIG. 2A, with the cable organizing device in the closed position and the desktop represented, is shown at 207.

Referring to FIG. 2I, an isometric side view of the right side of the desk frame of FIG. 2A, with the cable organizing device in the closed position, the desktop represented, and mounting plates removed, is shown at 208.

Referring to FIG. 2J, an isometric side view of the right side of the desk frame of FIG. 2A, with the cable organizing device in the open position, the desktop represented, and mounting plates removed, is shown at 209.

In some embodiments, the working surface comprises a tabletop, a seat of a chair, a workbench, or a shelf. In some embodiments, the tray is prevented from opening when the desk is lowered by one or more stops mounted on one or more of the two legs. In some embodiments, the stops comprise a crossbar support, pegs, pads, protrusions, or combinations thereof

In some embodiments, the latching apparatus comprises a hook, a hasp, a slide bolt, a magnet, pins, or combinations thereof. In some embodiments, the latching apparatus further comprises a lock.

In some embodiments, rotation of the hinge points is hindered such that the tray rotates opens slowly. This hindered rotation can be provided by soft-close or soft-down style hinges. These are hindered by springs, gas struts, or combinations thereof.

In some embodiments, a fan is provided mounted through at least one sidewall to cool electrical components stored in the tray.

In some embodiments, the tray floor comprises hook and loop, double-sided detachable tape, Pedalboard® tape, or combinations thereof, to which electrical components are removably attached.

In some embodiments, one or more motors rotate the tray around the hinge points. In some embodiments, one or more electrical sockets are mounted to the distal back wall. In some embodiments, a power cable for the one or more electrical cables passes through a gap in a lower portion of the distal back wall.

We claim:

1. A cable organizing device comprising:
a tray, mountable adjacent an underside of a working surface, comprising:
opposed side walls,
a tray floor, the tray floor comprising a U-shaped trough along a proximal side forming a front side wall of the tray
a distal back wall joined by the tray floor, the distal back wall comprising notches along its upper edge opposite the floor; and,
side walls, the side walls comprising a distal portion, the distal portion comprising mounting tabs comprising an eccentric hinge point around which the tray rotates elliptically, rotating the back wall of the tray away from the underside of the working surface, wherein, as the tray is rotated away from the underside of the working surface:
an opening is formed above the back wall to allow electrical cable components to pass the notches into the tray; and,
loose cable components in the tray slide into the U-shaped trough.

2. The cable organizing device of claim 1, wherein the working surface comprises a desktop, a tabletop, a seat of a chair, a workbench, or a shelf.

3. The cable organizing device of claim 2, wherein the desktop is mounted on two parallel crossbeams which are mounted on two legs.

4. The cable organizing device of claim 3, wherein the tray is mounted between the two parallel crossbeams.

5. The cable organizing device of claim 4, wherein the tray is shaped to match an underside profile of the working surface when the tray is closed.

6. The cable organizing device of claim 5, wherein the desktop is further mounted on a perpendicular crossbeam, the U-shaped trough aligning with a bottom portion of the perpendicular crossbeam.

7. The cable organizing device of claim 6, wherein a distal wall of the perpendicular crossbeam is proximate to an interior of the cable tray, the distal wall comprising one or more holes through which cables are passed.

8. The cable organizing device of claim 7, wherein the two legs comprise motors which automatically raise and lower the desk, and the cables for the motors pass through the cable tray via the perpendicular crossbeam.

9. The cable organizing device of claim 8, wherein the tray is prevented from opening when the desk is lowered by one or more stops mounted on one or more of the two legs.

10. The cable organizing device of claim 9, wherein the stops comprise a crossbar support, pegs, pads, protrusions, or combinations thereof.

11. The cable organizing device of claim 1, wherein the U-shaped trough comprises an attachment apparatus that holds the tray closed by attaching to the underside of the working surface.

12. The cable organizing device of claim 11, wherein the latching apparatus comprises a hook, a latch, a hasp, a slide bolt, a magnet, pins, or combinations thereof.

13. The cable organizing device of claim 12, wherein the latching apparatus further comprises a lock.

14. The cable organizing device of claim 1, wherein the tray is in a first position when the cable organizing device is in a fully open position, and wherein the tray is in a second position when the cable organizing device is in a fully-closed position, and wherein the first position is substantially perpendicular to second position.

15. The cable organizing device of claim 1, wherein rotation of the hinge points is hindered such that the tray rotates opens slowly.

16. The cable organizing device of claim 1, further comprising a fan, wherein the fan is mounted through at least one sidewall to cool electrical components stored in the tray.

17. The cable organizing device of claim 1, wherein the tray floor comprises hook and loop, double-sided detachable tape, Pedalboard® tape, or combinations thereof, to which electrical components are removably attached.

18. The cable organizing device of claim 1, wherein one or more motors rotate the tray around the hinge points.

19. The cable organizing device of claim 1, wherein one or more electrical sockets are mounted to the distal back wall.

20. The cable organizing device of claim 19, further comprising a power cable for the one or more electrical cables, wherein the power cable passes through a gap in a lower portion of the distal back wall.
